(19) United States
(12) Patent Application Publication
(10) Pub. No.: US 2019/0164727 A1
(43) Pub. Date: May 30, 2019

(54) PART FOR SEMICONDUCTOR MANUFACTURING APPARATUS AND SEMICONDUCTOR MANUFACTURING APPARATUS

(71) Applicant: Tokyo Electron Limited, Tokyo (JP)

(72) Inventors: Naoki SUGAWA, Miyagi (JP); Naoyuki SATOH, Miyagi (JP); Kazuya NAGASEKI, Miyagi (JP)

(21) Appl. No.: 16/196,088

(22) Filed: Nov. 20, 2018

(30) Foreign Application Priority Data
Nov. 29, 2017 (JP) 2017-229015

(51) Int. Cl. H01J 37/32; H01L 21/683

(52) U.S. Cl. CPC H01J 37/32642; H01L 21/67069; H01L 21/6831; H01J 37/32715

(57) ABSTRACT

A part for a semiconductor manufacturing apparatus, the part being enabled to cause electricity to pass through and including an insulating member.

### CROSS-REFERENCE TO RELATED APPLICATIONS

This patent application is based on and claims priority to Japanese Patent Application No. 2017-229015 filed on Nov. 29, 2017, the entire contents of which are incorporated herein by reference.

### BACKGROUND OF THE INVENTION

### 1. Field of the Invention

The present invention relates to a part for a semiconductor manufacturing apparatus and the semiconductor manufacturing apparatus.

### 2. Description of the Related Art

A focus ring is disposed at a peripheral edge portion of a wafer on a mounting stage inside a treatment chamber of a semiconductor manufacturing apparatus. The focus ring causes the plasma to be converged onto the surface of the wafer W when a plasma process is performed inside the treatment chamber. At this time, the focus ring is exposed to the plasma so as to be worn.

As a result, an irradiation angle of ions at the edge portion of the wafer W slants so as to cause tilting in an etching shape. Further, the etching rate in the edge portion of the wafer varies so as to make the etching rate on the surface of the wafer W uneven. Therefore, after the focus ring wears to a predetermined extent, the worn focus ring is ordinarily replaced to a new focus ring. However, an exchange time occurring at that time is one reason why the productivity is lowered.

On the contrary, it is proposed to control an in-plane distribution of the etching rate by applying a direct current output from the a direct current power source to the focus ring so as to control an in-plane distribution of the etching rate (for example, see Patent Document 1).

### [Patent Document 1] Japanese Laid-open Patent Publication No. 2009-239222

### SUMMARY OF THE INVENTION

There is provided a part for a semiconductor manufacturing apparatus, the part being enabled to cause electricity to pass through and including an insulating member.

### BRIEF DESCRIPTION OF THE DRAWINGS

FIG. 1 illustrates an example of a cross-sectional view of a semiconductor manufacturing apparatus of an embodiment.

FIGS. 2A and 2B explain a variation of an etching rate and tilting caused by wearing of a focus ring.

FIG. 3 illustrates an example of a cross-sectional view of the focus ring of the embodiment.

FIG. 4 illustrates an example of the upper surface of the focus ring of the embodiment.

FIG. 5 illustrates an example of a property of an insulating member of the embodiment.

FIGS. 6A-6D illustrate an example of a cross-sectional view of the focus ring of a modified example of the embodiment.

### DETAILED DESCRIPTION OF EMBODIMENTS

According to Patent Document 1, there is a problem that controllability of an etching rate and tilting because a change in sheath formed on the surface of the focus ring is great and a state change of the plasma is great.

In a manner similar thereto, in a member that is used for the semiconductor manufacturing apparatus except for the focus ring and wears by exposing the member to the plasma, sheath formed on the surface of the member changes due to wearing of the member so that the state of the plasma changes.

To solve the above problems, according to the embodiment of the present invention, controllability of at least one of etching rate and tilting is improved.

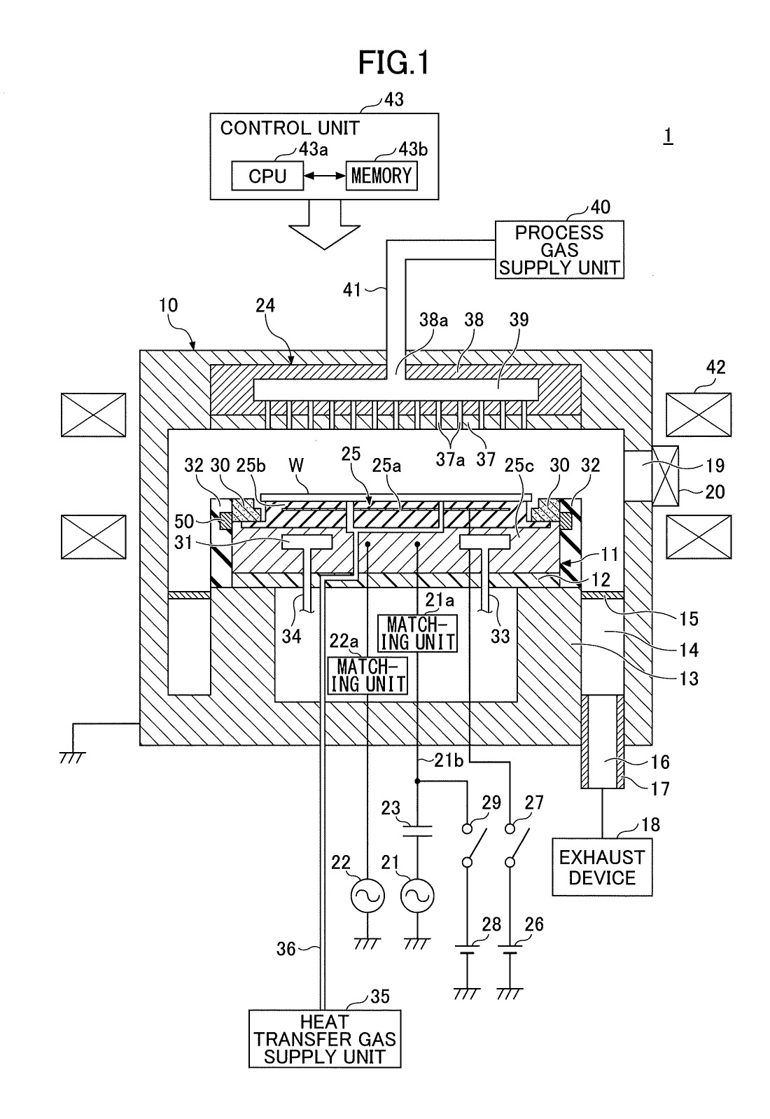

A description of embodiments of the present invention is given below, with reference to the FIG. 1 through FIG. 6D. The embodiments described below are only examples and the present invention is not limited to the embodiments.

Through all figures illustrating the embodiments, the same references symbols are used for portions having the same function, and repetitive explanations of these portions are omitted.

Reference symbols typically designate as follows:

1: semiconductor manufacturing apparatus;
10: processing container;
11: mounting stage;
15: baffle plate;
18: exhaust device;
21: first high-frequency power source;
22: second high-frequency power source;
23: blocking capacitor;
25: electrostatic chuck;
25a: adsorption electrode;
25b: dielectric layer;
25c: base;
26: direct current power source;
28: direct current power source;
30: focus ring;
30a: member;
305: ring-shaped protrusion portion;
30c: insulating member;
30d: space;
31: refrigerant chamber;
35: heat transfer gas supply unit;
43: control unit; and
50: aluminum ring.

### [Semiconductor Manufacturing Apparatus]

Referring to FIG. 1, an example of a semiconductor manufacturing apparatus of an embodiment is described. FIG. 1 illustrates an example of a cross-sectional view of a semiconductor manufacturing apparatus of an embodiment. The semiconductor manufacturing apparatus 1 of this embodiment is a semiconductor manufacturing apparatus of a reactive ion etching (RIE) type.

The semiconductor manufacturing apparatus 1 includes a processing container 10 that is in a shape of cylinder and is made of a metal such as aluminum and stainless steel. The inside of the processing container 10 functions as a treatment chamber performing a plasma process such as plasma etching and plasma CVD. The processing container 10 is grounded.

The mounting stage 11 in a disk-like shape is provided inside the processing container 10. A semiconductor wafer (hereinafter, referred to as a “wafer W”) is mounted on the mounting stage 11 as an object to be processed. The mounting stage 11 includes an electrostatic chuck 25. The mounting stage 11 is supported by a cylindrical supporter 13 that upward and vertically extends from the bottom of the processing container 10 interposing a cylindrical retaining member 12 made of alumina (Al₂O₃).

The electrostatic chuck 25 includes a base 25c made of aluminum and a dielectric layer 25b provided on the base 25c. A focus ring 30 is installed in a peripheral edge portion of the electrostatic chuck 25. The outer peripheries of the electrostatic chuck 25 and the focus ring 30 are covered by an insulator ring 32. An aluminum ring 50 is provided on an inner side surface of the insulator ring 32 so that the aluminum ring 50 contacts the focus ring 30 and the base 25c.

An adsorption electrode 25a including an conductive film is embedded in the dielectric layer 25b. A direct current power source 26 is connected to the adsorption electrode 25a through a switch 27. The electrostatic chuck 25 generates electrostatic force such as Coulomb force by direct current applied from a direct current power source 26 to the adsorption electrode 25a. The wafer W is adsorbed and held by this electrostatic force.

A first high-frequency power source 21 is connected to the mounting stage 11 through a matching unit 21a. The first high-frequency power source 21 applies high-frequency power having a first frequency (for example, frequency of 13 MHz) for generating plasma and for RIE to the mounting stage 11. A second high-frequency power source 22 is connected to the mounting stage 11 through the matching unit 22a. The second high-frequency power source 22 applies high-frequency power having a second frequency (for example, frequency of 3 MHz) that is lower than the first frequency for applying bias to the mounting stage 11. With this, the mounting stage 11 functions also as a lower electrode.

The direct current power source 28 is connected to the feed line 21b through a switch 28. Between a connecting point of connecting the direct current power source 28 to a feed line 21b and the first high-frequency power source 21, a blocking capacitor 23 is provided. The blocking capacitor 23 cuts off a direct current from the direct current power source 28 so as to prevent the direct current from flowing into the first high-frequency power source 21. The electrostatic chuck 25 generates electrostatic force such as Coulomb force by the direct current applied from the direct current power source 28. The focus ring 30 is adsorbed and held by this electrostatic force.

A ring-like refrigerant chamber 31 extending on, for example, a circumferential direction is provided inside the base 25c. A refrigerant, for example, cooling water having a predetermined temperature is supplied from the chiller unit and circulates through a pipe to an electrostatic chuck 25 to cool the electrostatic chuck 25.

The heat transfer gas supply unit 35 is connected to the electrostatic chuck 25 through the gas supply line 36. The heat transfer gas supply unit 35 supplies the heat transfer gas through the gas gas supply line 36 to a space between the upper surface of the electrostatic chuck 25 and the back surface of the wafer W. The heat transfer gas is preferably a gas having heat conductivity such as a He gas.

An exhaust passage 14 is formed between the sidewall of the processing container 10 and a cylindrical supporter 13. A ring-like baffle plate 15 is disposed at an inlet of the exhaust passage, and an exhaust port 16 is provided in a bottom portion. The exhaust device 18 is connected to the exhaust port 16 through the exhaust pipe 17. The exhaust device 18 includes a vacuum pump and depressurizes a processing space inside the processing container 10 to be a predetermined degree of vacuum. The exhaust pipe 17 has an automatic pressure control valve (APC) that is a variable butterfly valve 17, which automatically performs a pressure control inside the processing container 10. A gate valve 20 for opening or closing a carry-in and carry-out port for the wafer W is attached to the sidewall of the processing container 10.

A gas shower head 24 is provided in a ceiling portion of the processing container 10. The gas shower head 24 includes an electrode plate 37 and an electrode supporter 38 that attachably and detachably supports the electrode plate 37. The electrode plate 37 has a large number of gas vents 37a. A buffer chamber 39 is provided in the electrode supporter 38. A process gas supplying portion 40 is connected to the gas introduction port 38a of the buffer chamber 39 through a gas supplying pipe 41. A magnet 42 shaped like a ring or coaxially extending is arranged in a periphery of the processing container 10.

The composing elements of the semiconductor manufacturing apparatus 1 are connected to a control unit 43. The control unit 43 controls the composing elements of the semiconductor manufacturing apparatus 1. The composing elements are, for example, the exhaust device 18, the matching units 21a and 22a, the first high-frequency power source 21, the second high-frequency power source 22, the switches 27 and 29, the direct current power sources 26 and 28, the heat transfer gas supply unit 35, the process gas supplying portion 40, and so on.

The control unit 43 includes a CPU 43a and a memory 43b, and reads and executes a control program of the semiconductor manufacturing apparatus 1 stored in the memory 43b and a processing recipe to cause the semiconductor manufacturing apparatus 1 to execute a predetermined process such as etching. Further, the control unit 43 controls an electrostatic adsorption process for electrostatically adsorbing the wafer W, the focus ring 30, and so on in response to a predetermined process.

In the semiconductor manufacturing apparatus 1, for example, when the etching process is performed, the gate valve 20 is firstly opened, the wafer W is carried inside the processing container 10 and is mounted on the electrostatic chuck 25. A direct current from the direct current power source 26 is applied to the adsorption electrode 25a, the wafer W is caused to be absorbed to the electrostatic chuck 25, a direct current from the direct current power source 28 is applied to the base 25c, and the focus ring 30 is caused to be adsorbed to the electrostatic chuck 25. Further, the heat transfer gas is supplied between the electrostatic chuck 25 and the wafer W. Then, the process gas from the process gas supplying portion 40 is introduced inside the processing container 10, and the inside of the processing container 10 is depressurized by the exhaust device 18 or the like. Furthermore, the first high frequency power and the second high frequency power are respectively supplied from the first high-frequency power source 21 and the second high-frequency power source 22 to the mounting stage 11.

A horizontal magnetic field directing in one direction is formed by a magnet 42 inside the processing container 10 of the semiconductor manufacturing apparatus 1. An RF electric field is formed in the vertical direction by high-frequency power applied by the mounting stage 11. With this, a process gas ejected from the gas shower head 24 is converted to plasma. A predetermined plasma process is performed by radicals and ions in the plasma.

### [Wear of the Focus Ring]

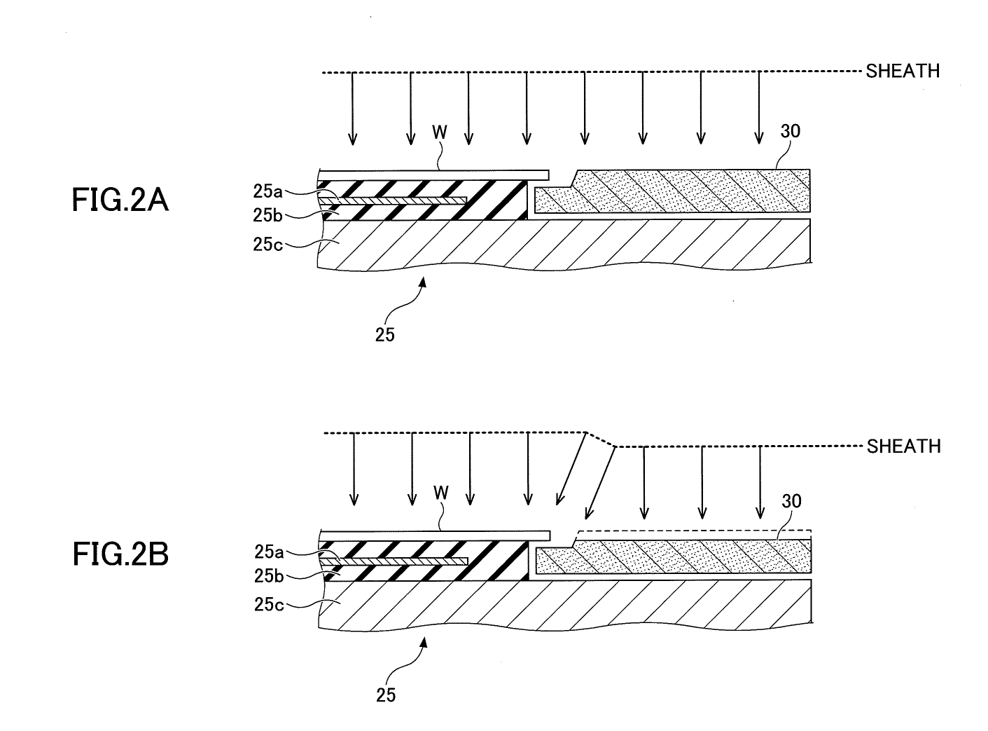

Referring to FIG. 2, a change of sheath generated by wear of the focus ring 30 and variations of an etching rate and tilting are described. Referring to FIG. 2A, when the focus ring 30 is new, the thickness of the focus ring 30 is designed so that the upper surface of the wafer W and the upper surface of the focus ring 30 have the same height. At this time, the sheath on the wafer W being subjected to the plasma processing and the sheath on the wafer W have the same height. In this state, the irradiation angle of ions from plasma onto the wafer W and the focus ring 30 is vertical. As a result, an etching shape of a hole formed on the wafer W is vertical, and tilting, in which the etching shape slants, is not caused. Further, the etching rate is controlled to be uniform in an entire surface of the wafer W.

However, the focus ring 30 is exposed to the plasma and wears during the plasma processing. Then, as illustrated in FIG. 2B, the upper surface of the focus ring 30 is made lower than the upper surface of the wafer W, and the height of the sheath over the focus ring 30 is made lower than the height of the sheath over the wafer W.

At an edge portion of the wafer W, in which a step is formed between the heights of the sheaths, the irradiation angle slants so as to cause the tilting in the etching shape. Further, the etching rate in the edge portion of the wafer W varies so as to make the etching rate on the surface of the wafer W non-uniform.

On the contrary thereto, within this embodiment, the direct current output from the direct current power source 28 is applied to the focus ring 30 so that the in-plane distribution of the etching rate and the tilting are controlled. However, if the direct current is applied from the entire upper surface of the focus ring 30 to the plasma space, the sheath of the the entire upper surface of the focus ring 30 changes. Therefore, the state change of the plasma is enhanced and controllability of the etching rate and the tilting are spoiled.

Then, in order to improve controllability of the etching rate and the tilting in the focus ring 30 of the embodiment, the focus ring 30 is structured so that a part of the sheath on the upper surface of the focus ring 30 changes.

### [Structure of the Focus Ring]

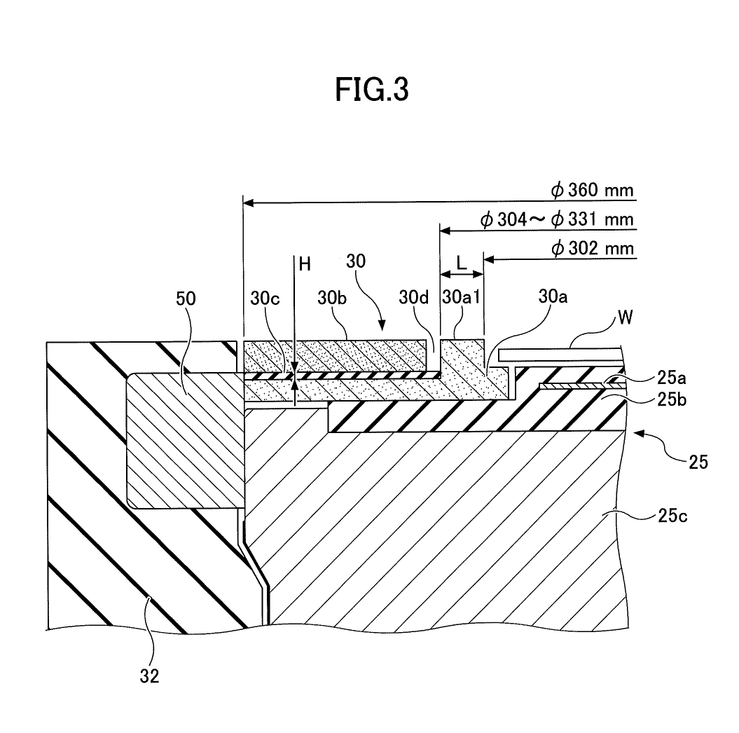

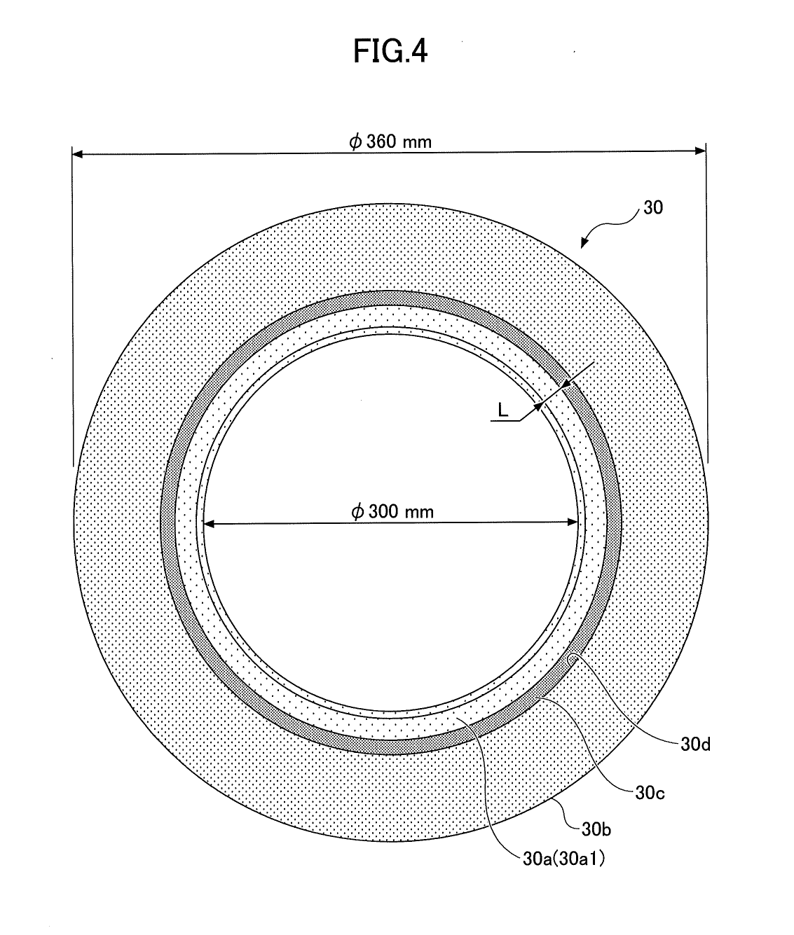

Referring to FIGS. 3 and 4, an example of the structure of the focus ring 30 of this embodiment is described below. FIG. 3 is a cross-sectional view of an example of the focus ring 30 and its vicinity according to this embodiment. FIG. 4 illustrates an example of the upper surface of the focus ring of this embodiment.

Within this embodiment, the focus ring may be divided into two ring-like members 30a and 30b that are made of silicon. The ring-like member 30a includes a protrusion 30a1 protruding from the upper surface of the focus ring 30 on an inner peripheral side of the focus ring 30. The focus ring 30 is disposed on the electrostatic chuck 25 so that the protrusion 30a1 approaches the peripheral edge portion of the wafer W. The outer peripheral side of the protrusion 30a1 of the member 30a is thinner than the protrusion 30a1 and has a flat profile.

A part of the focus ring 30 is made of an insulating member 30c shaped like a ring. Within the embodiment, a member 30b is mounted on the upper portion of the member 30a through the insulating member 30c shaped like the ring on the outer peripheral side of the protrusion 30a1.

The insulating member 30c may be a bond for casing the members 30a and 30b, which can be divided from the focus ring 30, to be mutually bonded so as not to be electrically connected. The insulating member 30c is made of SiO₂ of an inorganic substance or an organic substance of silicone, acrylic, or epoxy. There is a gap between the members 30a and 30b, and the insulating member 30c is exposed in the gap that is the upper surface of the focus ring.

As described above, it is structured that the members 30a and 30b are prevented from contacting. Therefore, the members 30a and 30b are prevented from electrically contacting.

However, the shape of the insulating member 30c is not limited to the ring-like shape. For example, the insulating member 30c may be installed in a portion of the focus ring 30 in a slit-like shape or in an island-like shape. In this case, the insulating member 30c or the gap is provided to prevent the members 30a and 30b from contacting or to prevent the members 30a and 30b from contacting as much as possible. Thus, it is possible to prevent an electrical contact between the members 30a and 30b or minimize the electrical contact between the members 30a and 30b.

Referring to FIG. 4, the outer diameter of the focus ring 30 is ϕ360 mm and the inner diameter is ϕ300 mm. However, the outer diameter and the inner diameter are not limited thereto. For example, the outer diameter of the focus ring 30 may be ϕ380 mm or else. For example, the inner diameter of the focus ring 30 may be ϕ302 mm or else. The width L of the ring on the upper surface of the protrusion 30a1 illustrated in FIGS. 3 and 4 may be at least 0.5 mm and preferably in a range of 0.5 mm to 30 mm.

When the gap 30d between the members 30a and 30b becomes at least 100 μm, the plasma generated above the focus ring 30 and the wafer W enters into the gap 30d so as to generate abnormal electrical discharge. Therefore, the gap 30d is controlled to be at most 100 μm, for example.

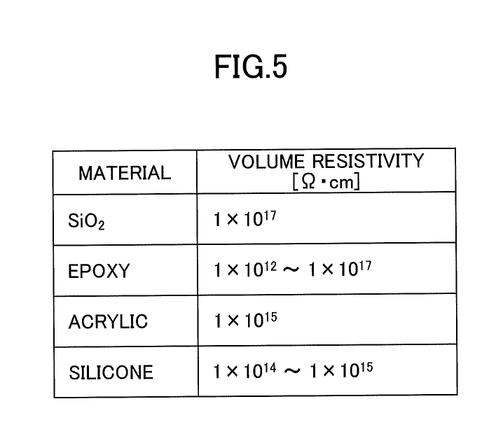

The insulating member 30c may be material having a volume resistivity in a range of 1×10¹²˜1×10¹⁷ [Ω·cm]. For example, the insulating member 30c may be a film made of any one of an inorganic substance of SiO₂ or an organic substance of silicone, acrylic, or epoxy. Referring to FIG. 5, the volume resistivity of SiO₂ is 1×10¹⁷[Ω·cm]. Further, the volume resistivity of epoxy is in a range of 1×10¹²˜1×10¹⁷ [Ω·cm], the volume resistivity of acrylic is in a range of 1×10¹²˜1×10¹⁷ [Ω·cm], and the volume resistivity of epoxy is in a range of 1×10¹⁴ to 1×10¹⁵ [Ω·cm]. Therefore, any material of SiO₂, silicone, acrylic, and epoxy is material whose volume resistivity is in a range of 1×10¹² to 1×10¹⁷ [Ω·cm].

The thickness H of the insulating member 30c may be in a range of 2 μm to 750 μm. For example, in a case where the insulating member 30c is SiO₂, the thickness H of the insulating member 30c may be any thickness within a range between 2 μm and 30 μm. In a case where the insulating member 30c is any one of silicone, acrylic, and epoxy, the thickness H of the insulating member 30c may be any thickness within a range between 2 μm and 750 μm.

At least one insulating member 30c may be provided on an inner peripheral side, an outer peripheral side, or at a predetermined height between the inner peripheral side and the outer peripheral side. The predetermined height means the upper surface of the focus ring 30 or the inside of the focus ring 30.

### [Path for Direct Current]

The direct current is applied from the direct current power source 28 to the electrostatic chuck 25. As illustrated in FIG. 3, the focus ring 30 and the base 25c are electrically stably connected through the aluminum ring 50. Within the embodiment, the side surface of the focus ring 30 contacting the aluminum ring 50 is a contact point as an entrance of the direct current. However, the position of the contact is not limited thereto.

The direct current sequentially flows in an order of the base 25c, the aluminum ring 50, and the focus ring 30. Inside the focus ring 30, the insulating member 30c is a resistor layer. The direct current is prevented by insulating member 30c from flowing into the member 30b separated by the member 30a.

Therefore, the direct current flows inside the focus ring 30 through a path determined by aligning the insulating member 30c from the contact point as the entrance of the direct current. Said differently, the direct current enters from the outer surface on the outer peripheral side of the member 30a, flows toward the inner peripheral side, and reaches the plasma space from the inner peripheral upper surface (the upper surface of the protrusion 30a1 in the ring-like shape) as an exit of the direct current. The width L on the upper surface of the protrusion 30a1 in the ring-like shape as the exit of the direct current is preferably at least 0.5 mm.

As described above, according to the focus ring 30 of this embodiment, the protrusion 30a1 of the member 30a being the path of the direct current is provided so as to upward protrude on the inner peripheral side of the focus ring 30. The insulating member 30c separates the member 30a from the member 30b on the outer peripheral side of the focus ring 30. Further, a gap 30d is provided on the inner peripheral side so that the members 30a and 30b do not contact. With this structure, the direct current is caused to flow from the upper surface of the protrusion 30a1 on the inner peripheral side from among the upper surface of the focus ring 30 illustrated in FIG. 4 to prevent the direct current from flowing from the upper surface of the member 30b on the outer peripheral side to the plasma space.

When the direct current flows through the plasma space from the entire upper surface of the focus ring 30, a change of the sheath formed on the focus ring becomes great. With this, the state change of the plasma becomes large to degrade controllability of etching rate and tilting. On the contrary, within this embodiment, the direct current flows through the path of the focus ring determined by aligning the insulating member 30c and reaches the plasma space from a portion of the upper surface of the focus ring 30. With this, the change of the sheath on the focus ring 30 can be made partial, and only an area in which the sheath is required to be changed can be changed. Therefore, the state change of the plasma occurs in a small portion, and the controllability of the etching rate and the tilting can be improved. As a result, the tilting can be prevented from occurring and the etching shape can be made vertical. Further, the etching rate on the surface of the wafer W can be made even.

Referring to FIG. 3, the gap is present between the focus ring 30 and the base 25c, and the direct current sequentially flows through the base 25c, the aluminum ring 50, and the focus ring 30, which are electrically connected. However, the structure is not limited thereto. For example, by causing the lower surface of the focus ring 30 to contact with the base 25c, the lower surface of the focus ring 30 becomes the contact point as the entrance of the direct current.

For example, in a case where the focus ring 30 is caused to contact the aluminum ring 50 at the lower surface of the focus ring 30, the lower surface of the focus ring 30 becomes the entrance of the direct current.

Further, it is preferable to coat a portion of the side surface of the base 25c with a thermal spray film that is formed by providing thermal spray of yttria (Y203) or the like to prevent the direct current from flowing through the portion.

### Modified Example

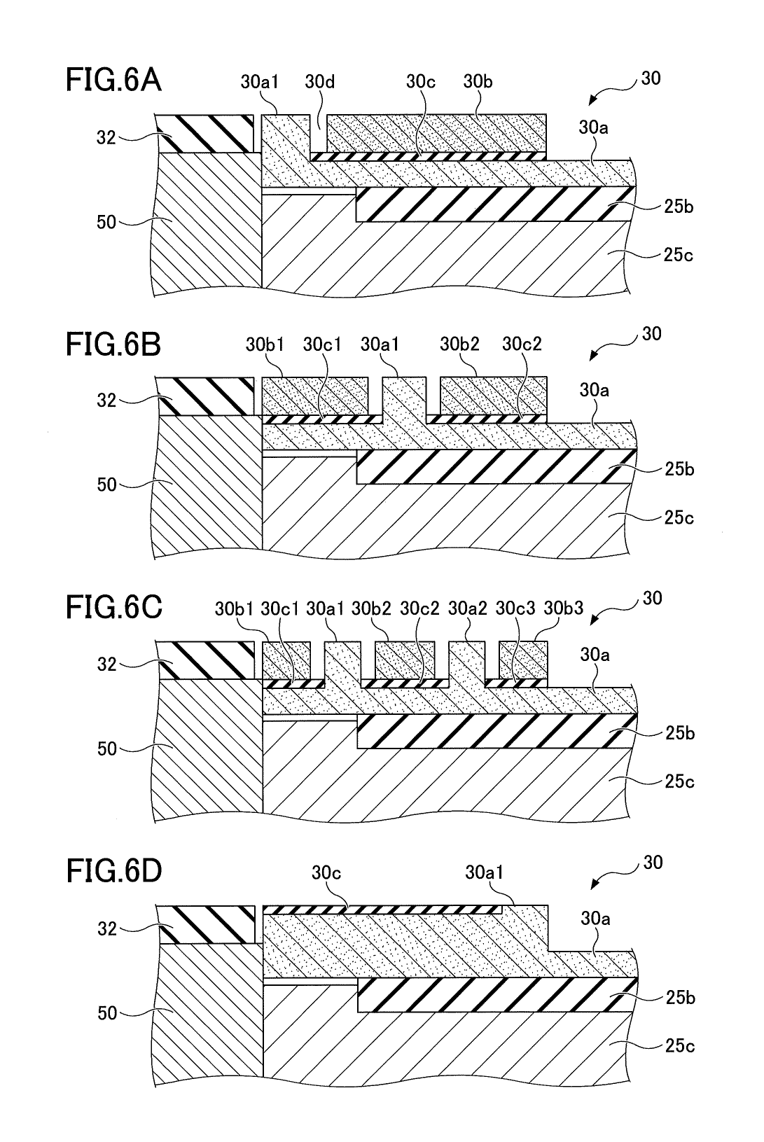

Finally, the focus ring 30 of the modified example of the embodiment is described with reference to FIGS. 6A to 6D. FIGS. 6A-6D illustrate examples of cross-sectional views of the focus ring of this embodiment.

### Modified Example 1

In the focus ring 30 of the modified example 1 illustrated in FIG. 6A, the protrusion 30a1 of the member 30a being the exit of the direct current is provided on the outer peripheral side of the focus ring 30 in the ring-like shape. The insulating member 30c separates the member 30a from the member 30b on the inner peripheral side of the focus ring 30. Further, a gap 30d is provided on the outer peripheral side so that the members 30a and 30b do not contact. The other structures are the same as those of the focus ring 30 according to the embodiment illustrated in FIG. 3.

The direct current enters from the outer peripheral side of the member 30a, flows through the outer peripheral side, and reaches the plasma space from the upper surface of the protrusion 30a1 in the ring-like shape as an exit of the direct current.

### Modified Example 2

In the focus ring 30 of the modified example 2 illustrated in FIG. 6B, the protrusion 30a1 of the member 30a being the exit of the direct current is provided on a center of the focus ring 30 in the ring-like shape. Insulating members 30c1 and 30c2 separate members 30a and 30b1 and members 30a and 30b2 respectively on the outer peripheral side and the inner peripheral side of the focus ring 30. In the center, gaps are formed to prevent the members 30a and 30b1 from contacting and to prevent the members 30a and 30b2 from contacting. The other structures are the same as those of the focus ring 30 according to the embodiment illustrated in FIG. 3.

The direct current enters from the outer peripheral side of the member 30a, flows towards the center, and reaches the plasma space from the upper surface of the protrusion 30a1 in the ring-like shape at the center.

### Modified Example 3

In the focus ring 30 of the modified example 3 illustrated in FIG. 6C, two protrusions 30a1 and 30a2 of the member 30a being the exits of the direct current are respectively provided between the outer peripheral side and the center of the focus ring 30 in the ring-like shape and between the inner peripheral side and the center of the focus ring 30. Insulating members 30c1, 30c2, and 30c3 separate members 30a and 30b1, members 30a and 30b2, and members 30a and 30b3 on the outer peripheral side, the center, and the inner peripheral side of the focus ring 30, respectively. Gaps are formed to prevent the members 30a and 30b1 from contacting, to prevent the members 30a and 30b2 from contacting, and to prevent the members 30a and 30b3 from contacting. The other structures are the same as those of the focus ring 30 according to the embodiment illustrated in FIG. 3.

In the modified example 3, the direct current enters from the outer peripheral side of the member 30a, flows towards the center, and reaches the plasma space from the upper surface of the protrusions 30a1 and 30a2 in the ring-like shape respectively between the outer peripheral side and the center and between the center and the inner peripheral side. In the modified example 3, the total widths of the upper surfaces of the protrusion 30a1 and the protrusion 30a2 are at least 0.5 mm and are preferably in a range of 0.5 mm to 30 mm.

### Modified Example 4

In the focus ring 30 of the modified example 4 illustrated in FIG. 6D, the protrusion 30a1 of the member 30a being the exit of the direct current is provided on the inner peripheral side of the focus ring 30 in the ring-like shape. The insulating member 30c is provided on the upper surface of the focus ring 30. In this case, the insulating member 30c may be formed by attaching a member such as an SiO₂ film in a sheet-like shape or depositing a film using a thermal spray film made of SiO2 by thermal spray as the insulating member 30c. However, in this case, the insulating member 30c is exposed to the plasma on the upper surface of the focus ring 30, it is necessary to coat the focus ring 30 by yttria (Y203) to enhance plasma durability. Within the embodiment, it is unnecessary to divide the focus ring 30 into multiple members.

In the modified example 4, the direct current enters from the outer peripheral side of the member 30a, flows towards the inner peripheral side, and reaches the plasma space from the upper surface of the Protrusion 30a1 in the ring-like shape.

In any one of the modified examples 1 to 4, the direct current is flown from a portion of the upper surface of the focus ring 30 to the plasma space to make the change of the sheath formed on the focus ring 30 small. Therefore, by making the state change of the plasma small, the controllability of the etching rate and the tilting can be improved. A component for the semiconductor manufacturing apparatus is preferably semiconductor such as silicon.

All examples and conditional language recited herein are intended for pedagogical purposes to aid the reader in understanding the invention embodiments and the concepts contributed by the inventor to furthering the art, and are to be construed as being without limitation to such specifically recited examples and conditions, nor does the organization of such examples in the specification relate to a showing of superiority or inferiority of the invention embodiments. Although a part for a semiconductor manufacturing apparatus of the present invention has been described in detail, it should be understood that the various changes, substitutions, and alterations could be made hereto without departing from the spirit and scope of the invention.

Within the above embodiment and the modified examples, the focus ring 30 is described. However, the part for the semiconductor manufacturing apparatus related to the present invention is not limited thereto. The part for the semiconductor manufacturing apparatus is sufficient to apply high-frequency power and a direct current and to be used for the semiconductor manufacturing apparatus. As an example, the part for the semiconductor manufacturing apparatus can be applied to an upper electrode for applying high-frequency power and the direct current. In this case, according to the present invention, even though the upper electrode wears by being exposed to the plasma, controllability of the etching rate and the tilting can be improved. However, it is sufficient that at least any one of the etching rate and the tilting is improved.

The semiconductor manufacturing apparatus of the embodiments may be any type of Capacitively Coupled Plasma (CCP), Inductively Coupled Plasma (ICP), Radial Line Slot Antenna, Electron Cyclotron

Resonance Plasma (ECR), and Helicon Wave Plasma (HWP).

Within the embodiment, the wafer W is mentioned as an example of an object to be processed by the semiconductor manufacturing apparatus 1. However, the object to be processed is not limited to this and may be various substrates used for a Liquid Crystal Display (LCD) and a Flat Panel Display (FPD), a Compact Disk (CD) substrate, a printed wiring board, and so on.

According to the invention, controllability of at least one of the etching rate or the tilting can be improved.

What is claimed is:

1. A part for a semiconductor manufacturing apparatus, the part being enabled to cause electricity to pass through, the part comprising:
an insulating member.

2. The part according to claim 1,
wherein a shape of the insulating member in the part is like a ring, a slit, or an island.

3. The part according to claim 2,
wherein a shape of the insulating member exposed from the part is like a ring, a slit, or an island.

4. The part according to claim 1,
wherein material forming a portion other than the insulating member in the part is a semiconductor.

5. The part according to claim 1,
wherein the insulating member is made of material whose volume resistivity is in a range of 1×10¹² to 1×10¹⁷ [Ω·cm].

6. The part according to claim 5,
wherein the insulating member is made of any one of silicon oxide, silicone, acrylic, or epoxy.

7. The part according to claim 1,
wherein the part causes a direct current to flow from a contact that is an entrance of the direct current to a path of the part determined by arranging the insulating member.

8. The part according to claim 7,
wherein a width of a surface in the ring-like shape is at least 0.5 mm, the surface of the ring-like shape being an exit of a direct current through a path of the part.

9. The part according to claim 1,
wherein a thickness of the insulating member is in a range of 2 μm to 750 μm.

10. The part according to claim 1,
wherein the part is a focus ring.

11. The part according to claim 10,
wherein the number of the insulating member is at least one, and the at least one insulating member is provided at a predetermined height on an inner peripheral side of the focus ring, an outer peripheral side of the focus ring, or on a side between the inner peripheral side and the outer peripheral side.

12. The part according to claim 1,
wherein the insulating member is a bond that bonds at least two members obtained by dividing the parts so as not to be electrically connected.

13. The part according to claim 1,
wherein the insulating member is a thermal spray film that is formed on a surface of the part by thermal spray.

14. A semiconductor manufacturing apparatus including
a mounting stage inside a treatment chamber;
an electrostatic chuck installed on the mounting stage; and
a focus ring installed on the electrostatic chuck and placed at a peripheral edge portion of an object to be processed,
wherein an insulating member is provided at a portion of the focus ring that is electrically conductive.
